(19) United States
(12) Patent Application Publication
(10) Pub. No.: US 2025/0208376 A1
(43) Pub. Date: Jun. 26, 2025

(54) ASSEMBLY OF AN OPTICAL SYSTEM

(71) Applicant: Carl Zeiss SMT GmbH, Oberkochen (DE)

(72) Inventors: Christoph Mueller, Aalen (DE); Norman Niewrzella, Aalen (DE)

(21) Appl. No.: 19/078,720

(22) Filed: Mar. 13, 2025

Related U.S. Application Data
(63) Continuation of application No. PCT/EP2023/073490, filed on Aug. 28, 2023.

(30) Foreign Application Priority Data
Sep. 23, 2022 (DE) 102022210087.5

(51) Int. Cl. G02B 7/18; G02B 7/182; G02B 17/00; G03F 7/00

(52) U.S. Cl. CPC G02B 7/1815; G02B 7/182; G02B 17/002; G03F 7/70233; G03F 7/70833; G03F 7/70891

(57) ABSTRACT

An assembly of an optical system, comprising at least one mirror with a mirror main body, in which there is a fluid channel arrangement with at least one fluid channel through which a fluid can flow. The fluid channel arrangement is coupled to a fluid line system via a detachable flange connection. The flange connection comprises a flange interface formed on the mirror main body and a flange force-lockingly mounted on the flange interface. A seal is formed between the flange and the flange interface in order to provide a differential vacuum.

### CROSS-REFERENCE TO RELATE APPLICATIONS

The present application is a continuation of, and claims benefit under 35 USC 120 to, international application No. PCT/EP2023/073490, filed Aug. 28, 2023, which claims benefit under 35 USC 119 of German Application No. 10 2022 210 087.5, filed Sep. 23, 2022. The entire disclosure of each of these applications is incorporated by reference herein.

### FIELD

The disclosure relates to an assembly for an optical system. For example, the optical system may be a beam guiding unit (“beamline”) of a synchrotron or a free-electron laser.

### BACKGROUND

For optical applications in the EUV range (e.g. wavelengths below 30 nm) or in the X-ray range (e.g. wavelengths below 0.1 nm), mirrors are used as optical components due to the general lack of availability of suitable light-transmissive refractive materials. Examples include synchrotron mirrors and mirrors that are used in the illumination device or the projection lens of a microlithographic projection exposure apparatus.

In practice, such mirrors can experience heating and an attendant thermal expansion or deformation, inter alia as a result of absorption of the incident radiation. The temperature profiles generated in the mirror substrate or on the optical effective surface in the process may possibly have as a consequence—especially in the case of comparatively strongly localized heat inputs of the incident electromagnetic radiation—a pronounced inhomogeneity over the optically used region with the result that the thermally induced deformation profiles resulting from the respective temperature profiles can cause optical aberrations, which cannot be corrected or can only be corrected with difficulties, during the operation of the respective optical system.

For example, this may be the case for a synchrotron mirror, in which, during the operation of the synchrotron, the current heat-affected zone corresponding to the currently optically used region is typically comparatively small in relation to the entire mirror surface and moreover can vary locally during operation. An impairment of the imaging properties of the optical system comprising the respective mirror may ultimately be the result.

Various approaches serving to prevent surface deformations caused by heat input and attendant optical aberrations are known, for example active cooling using fluid channels through which a (cooling) fluid can flow in each case.

However, in practice, depending on the implementation of the connection between mirror and cooling fluid supply system, further undesirable effects can arise as a result of mechanical, thermal and/or dynamic loads and limit the performance and service life of the optical system. For example, in the event of leaks, possibly complex repair processes or even a replacement of the entire mirror may be involved, resulting in considerable costs and moreover a reduction in the achievable throughput on account of the operational downtime. In addition, in the event of leaks there is also a risk of contamination of the optical system (that is typically operated under vacuum conditions) by escaping cooling fluid. Furthermore, the connection of the fluid channel arrangement and its operation may cause parasitic forces and attendant deformations of the mirror surface, which in turn can lead to optical aberrations.

Reference is made merely by way of example to U.S. Pat. No. 10,955,595 B2 and US 2015/0083938 A1.

### SUMMARY

The present disclosure seeks to provide an assembly for an optical system, the optical system enabling an effective avoidance of thermally induced deformations while alleviating the aforementioned problems.

In an aspect, the disclosure provides an assembly for an optical system, comprising at least one mirror with a mirror main body, extending through which there is a fluid channel arrangement having at least one fluid channel through which a fluid can flow. The fluid channel arrangement is coupled to a fluid line system by way of a releasable flange connection. The flange connection comprises a flange interface formed on the mirror main body and a flange frictionally mounted on this flange interface. A seal is formed between the flange and the flange interface in order to provide a differential vacuum.

For example, within an assembly of an optical system the disclosure is based on the concept of coupling a fluid channel arrangement, which serves to avoid or reduce thermally induced deformations, which allows a fluid to flow therethrough and which is found in a mirror main body of a mirror, to a fluid line system without an integral bond (for example “solder-free”) by way of a flange connection that is releasable in principle. In this case, a comparatively soft interface (“separation layer”) along the joining region is avoided by managing without the implementation of an integral bond (for example without the application of a soldering technique), whereby the attendant problems of such a separation layer are in turn avoided, both in thermal terms and under strength aspects. Moreover, as a consequence of the releasable connection, the corresponding component can be easily replaced in the event of a leak. Maintenance work is also considerably simplified in the assembly according to the disclosure, since, if desired, the flange can be simply unscrewed and screwed on again (e.g. after cleaning and optional insertion of a new seal), and the optical system can then be put back into operation immediately.

According to the disclosure, undesirable features, firstly as regards the installation space used for the realization of the screw connection, which is increased in comparison with a soldered connection, and secondly, however, also as regards the problem of introducing undesired mechanical stresses into the mirror, are deliberately accepted in this context. In principle, a coupling according to the disclosure by way of a flange can lead to an increase in the acting forces, inter alia as a result of the attachment of corresponding masses for the flange, any threaded plates, etc., whereby a risk of fractures occurring in the mirror main body and a risk of the deformations occurring can be in turn increased.

However, according to the disclosure, these disadvantages can be accepted deliberately, firstly in order to achieve the above-described advantages of a solderless connection and secondly due to the consideration that the aforementioned parasitic forces and attendant deformations may be significantly reduced or minimized by a suitable embodiment of the flange connection and for example of the flange interface formed on the mirror main body.

According to the disclosure, a seal is formed between the flange and the flange interface in order to provide a differential vacuum.

For the purposes of the present application, the term “differential vacuum” should be understood in this case to mean a vacuum located between a first vacuum and a second vacuum, the vacuum pressure of the differential vacuum having a value between that of the vacuum pressure present in the first vacuum and the vacuum pressure present in the second vacuum. In this context, the second vacuum may be present in the fluid channel arrangement and the first vacuum may be present in the outer surroundings of the mirror.

Quantitatively, for example, the vacuum pressure present in the first vacuum or in the outer surroundings of the mirror may be in the range of (10⁻⁹-10⁻¹²) mbar, the vacuum pressure present in the second vacuum or in the fluid channel arrangement may be in the range of (0.1-10) bar and the vacuum pressure present in the differential vacuum may be in the range of (10⁻³-10⁻⁴) mbar.

The differential vacuum (which may also be referred to as “support vacuum”) can allow tightness to be monitored in the assembly according to the disclosure. Any leaks can be detected in real time as a result of permanently monitoring the differential vacuum. The associated system or machine can be shut down as soon as contamination of this vacuum is detected. For example, this may take account of the fact that the mirror is operated in UHV surroundings (in the range from 10⁻¹⁰ mbar to 10⁻¹² mbar) when used as a synchrotron mirror and that the tightness standards are even higher than in comparison with EUV applications (10⁻⁹ mbar), for example.

According to one embodiment, the seal is a seal according to the double O-ring principle. Within the meaning of the present application, the phrase “seal according to the double O-ring principle” should also include a seal in which at least one of the two sealing rings or O-rings is replaced by a molded seal. In addition, the term “O-ring” within the meaning of the present application should also include seals with a polygonal cross-sectional profile.

According to one embodiment, a monitoring device is provided for monitoring a tightness of the flange connection as regards fluid escaping during the operation of the optical system.

In an aspect, the disclosure provides an optical system, comprising at least one mirror with a mirror main body, extending through which there is a fluid channel arrangement having at least one fluid channel through which a fluid can flow. The fluid channel arrangement is coupled to a fluid line system by way of a releasable flange connection. The flange connection comprises a flange interface formed on the mirror main body and a flange frictionally mounted on this flange interface. A monitoring device is provided for monitoring a tightness of the flange connection as regards fluid escaping during the operation of the optical system.

According to one embodiment, the monitoring device is configured to realize the monitoring of a tightness of the flange connection without influencing an external vacuum environment of the mirror.

According to one embodiment, the monitoring device is configured to detect fluid entering a region between the flange and the flange interface.

According to one embodiment, the monitoring device comprises a mass spectrometer, a gas detector or a moisture sensor.

According to one embodiment, the assembly comprises at least one further joining point in addition to the flange connection, wherein the monitoring device is also provided for monitoring a tightness of this further joining point as regards escaping fluid.

According to one embodiment, the flange interface takes the form of at least one decoupling structure that serves to reduce a transmission of force from the flange to the mirror main body.

According to one embodiment, this decoupling structure is formed by a tapered portion of the flange interface.

According to one embodiment, the fluid channel extends in an axial direction in this tapered portion, wherein the ratio between an axial extent of this tapered portion and a wall thickness of the tapered portion remaining toward the fluid channel is in the range of 1 to 5.

According to one embodiment, the flange is mounted on the flange interface by way of a screw connection.

According to one embodiment, this screw connection is implemented along a portion of the flange interface, wherein, for this portion, the ratio of its extent in a direction perpendicular to the screw direction to the extent in the screw direction is in the range of 2 to 10, for example in the range of 2 to 4.

According to one embodiment, the mirror comprises a cover plate which is bonded to the mirror main body and on which a reflection layer system is formed. In this context, the phrase “reflection layer system” should comprise both a single layer and a multilayer system.

According to one embodiment, the cover plate is connected monolithically to the mirror main body by way of a direct bonding or fusion bonding. These bonding processes can manage without auxiliary materials, and a monolithic component with optimized mechanical properties can be obtained due to the absence of a physical separation joint.

According to one embodiment, the mirror main body is produced from a silicon-containing material, for example a material from the group containing monocrystalline silicon (Si), silicon dioxide (SiO₂) and titanium dioxide-doped quartz glass.

According to one embodiment, the mirror is designed for an operating wavelength of less than 30 nm, for example less than 15 nm.

According to one embodiment, the mirror is designed for an operating wavelength of less than 0.1 nm.

According to one embodiment, the optical system is a beam guiding unit (“beamline”) of a synchrotron or a free-electron laser.

The disclosure also relates to an optical system having an assembly with the features described above.

According to one embodiment, the optical system is a synchrotron.

According to on embodiment, the optical system is a projection lens or an illumination device of a microlithographic projection exposure apparatus.

Further embodiments of the disclosure are evident from the description and the dependent claims.

The disclosure is elucidated in detail hereinafter with reference to exemplary embodiments shown in the appended figures.

### BRIEF DESCRIPTION OF THE DRAWINGS

In the figures:

FIG. 1 shows a schematic illustration for explaining a possible application of an assembly according to the disclosure in a synchrotron;

FIG. 2 shows a schematic illustration for explaining a possible embodiment of an assembly according to the disclosure;

FIGS. 3A-3B show schematic illustrations for explaining a further possible embodiment of an assembly according to the disclosure; and

FIG. 4 shows a schematic illustration of the possible structure of a microlithographic projection exposure apparatus designed for operation in the EUV.

### DETAILED DESCRIPTION

According to the disclosure, within an assembly of an optical system a fluid channel arrangement, which serves to avoid thermally induced deformations, which allows a cooling fluid to flow therethrough and which is found in a mirror main body of a mirror, is coupled to a fluid line system without an integral bond (for example in a “solder-free” manner) by way of flange connection that is releasable.

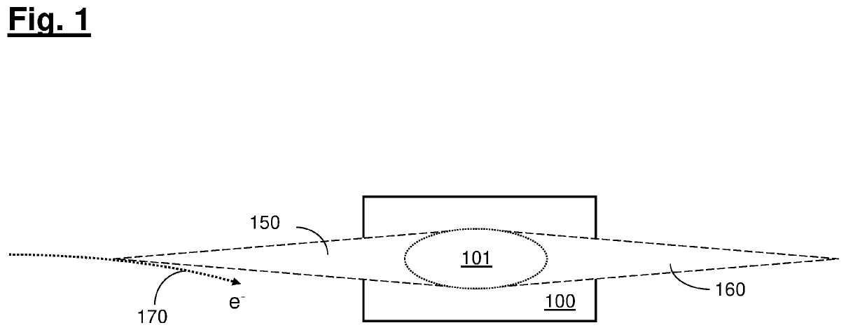

The mirror present in an assembly according to the disclosure can be used e.g. as a deflection mirror or beam guiding optical component in a synchrotron, as shown only schematically in FIG. 1 for a mirror 100. According to FIG. 1, in such a synchrotron, the electromagnetic radiation 150 (in the form of a divergent X-ray beam in the example) generated by acceleration or deflection of an electron beam 170 is incident on the mirror 100. For example, the mirror 100 may also be positioned in what is known as a “beamline”, on which the electromagnetic radiation generated in the synchrotron is incident. In this case, an elliptical “footprint” generated on the mirror 100 in the example is denoted by “101” as optically used region, and the electromagnetic radiation (in the form of a convergent X-ray beam in the example) emanating from the mirror 100 post reflection is denoted by “160”. In this case, the optically used region or “footprint” in the illustrated scenario is a comparatively strongly localized region on the mirror surface, the current position of which, however, may “migrate” or vary on the mirror surface. An assembly according to the disclosure serves for example to prevent or reduce deformations thermally induced by electromagnetic radiation.

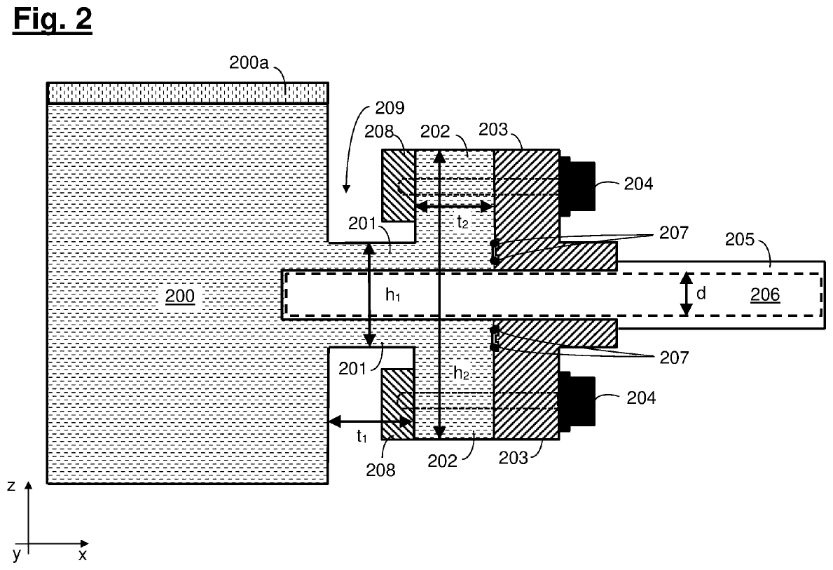

FIG. 2 shows a merely schematic illustration for explaining a possible embodiment of an assembly according to the disclosure. According to FIG. 2, the assembly comprises at least one mirror with a mirror main body 200. Moreover, the mirror comprises a cover plate 200a which is bonded to the mirror main body 200 and on which a reflection layer system (not illustrated here) is formed. Depending on the specific application scenario, the mirror may be a plane mirror or have any other (e.g. spherical or cylindrical) geometry.

In the specific exemplary embodiment, the mirror main body 200 is produced from monocrystalline silicon (Si), and the reflection layer system in the example comprises a single layer of gold (Au) with an exemplary thickness in the range of 20 nm to 50 nm. In further embodiments, the reflection layer may also be produced from another precious metal, for example platinum (Pt), rhodium (Rh), silver (Ag), ruthenium (Ru), palladium (Pd), osmium (Os) or iridium (Ir). Furthermore, the reflection layer may also be produced from an organic material, for example carbon (C), boron carbide (B₄C) or silicon carbide (SiC).

Depending on the intended use, the mirror may be a mirror designed for operation under grazing incidence or a mirror designed for operation under normal incidence. As reflection layer system, the mirror in the latter case typically comprises a multilayer system in the form of e.g. an alternating sequence of individual layers made of e.g. at least two different layer materials. Furthermore, in further embodiments, the mirror main body 200 or the mirror substrate may also be produced from another substrate material, e.g. a substrate material likewise containing silicon, for example silicon dioxide (SiO₂) or Zerodur® (by Schott AG). In addition, depending on the intended use, a titanium silicate glass sold as ULE® by Corning Inc., for example, may also be used as substrate material.

Without suitable countermeasures, the electromagnetic radiation incident on the mirror during operation leads to an undesirable temperature profile or deformation profile (with possibly large gradients in the optically used region) and attendant optical aberrations of the optical system comprising the mirror. In order to counteract such an undesirable temperature profile or deformation profile, a fluid channel arrangement 205 with at least one fluid channel 206 through which a fluid (e.g. water) can flow extends through the mirror main body 200, as indicated in FIG. 2. The fluid channel arrangement 205 is coupled to a fluid line system by way of a releasable flange connection, the flange connection comprising a flange interface 202 formed on the mirror main body 200 and a flange 203 frictionally mounted on this flange interface 202. For example, the flange 203 may be produced from stainless steel. The releasable flange connection is realized as a screw connection in the exemplary embodiment (but without the disclosure being limited thereto), for which purpose screws denoted by “204” in FIG. 2 are secured to threaded plates denoted by “208” (and also made of stainless steel in the embodiment).

As a result of the realization according to the disclosure of the desired coupling between the fluid channel arrangement, which extends within the mirror main body 200, and the outer fluid line system by way of a releasable flange connection with a frictional mount of the flange 203 on the flange interface 202, firstly the problems associated with a solder connection as regards the thermal connection and arising leaks are avoided and secondly maintenance work is also facilitated, as already set forth at the outset. In the event of a leak, a simple replacement of the affected releasably coupled component may moreover be carried out.

In return, however, according to the disclosure—as also described at the outset—there is an acceptance of problems which are connected with the attachment of additional masses due to the flange 203, the flange interface 202 and the threaded plates 208 and are also connected with the generation of additional (e.g. screw or clamping) forces for the production of the frictional coupling. These forces act on the mirror as disturbance forces or parasitic forces, in addition to the forces caused by the fluid flow in the fluid channel arrangement, and, in the absence of appropriate countermeasures, in turn cause undesirable deformations of the optical effective surface.

In order to reduce or minimize the influence of the creation of additional parasitic forces on the mirror deformations, which is accepted according to the disclosure, there can be, according to the disclosure, a targeted embodiment of the flange connection according to the disclosure with an appropriate design or optimization of the parameters described hereinafter.

In this case, it is assumed below (without the disclosure being limited thereto) that the flange 203 is mounted on the flange interface 202 by way of a screw connection. In further embodiments, the frictional mount of the flange 203 on the flange interface 202 may also be realized in another suitable manner, for example by way of a clamping connection, for example.

Initially as regards the reduction or minimization of deformations on account of the parasitic forces generated by the screw connection, the flange interface 202 in the embodiment of FIG. 2 is embodied in certain regions for the formation of a decoupling structure (or a decoupling joint) 201. The decoupling structure 201 is formed here by a tapered portion of the flange interface 202. According to FIG. 2, this is implemented by virtue of the wall thickness (h₁−d)/2 remaining toward the fluid channel 206 being reduced in comparison with the remaining, non-tapered portion of the flange interface 202 that faces the flange 203 by “cutting free” the flange interface 202 in the corresponding region 209 that faces the mirror main body 200. As a result of the thin wall in the region 209, deformations or transverse contractions that occur when the flange 203 is screwed-in are reduced in terms of their influence on the optical effective surface of the mirror.

At the same time, the stiffness of the flange interface 202 in the “axial” direction (i.e. in the x-direction of the plotted coordinate system) is increased by a suitable choice of a comparatively large dimension t₂. In addition, this stiffness, which is predominantly relevant to the effects of prestressing forces of the screw connection, may also be increased by increasing the dimension h₂ (whereby the parameter h₂ in this respect is of less influence than the parameter t₂). The ratio h₂/t₂ may be optimized according to the specific application scenario and can be in the range of 2 to 10, such as in the range of 2 to 4.

In the exemplary embodiment of FIG. 2, the screw connection is thus implemented along a portion of the flange interface 202, wherein, for this portion, the ratio of its extent in a direction perpendicular to the screw direction to the extent in the screw direction can be in the range of 2 to 10 (but without the disclosure being limited thereto), such as in the range of 2 to 4.

The aforementioned decoupling effect of the decoupling structure 201 in the x-direction of the plotted coordinate system may also additionally be achieved by a suitable enlargement of the dimension t₁ in order to influence the flexural stiffness of the decoupling structure 201, this parameter however being of comparatively less influence in this respect than the wall thickness (h₁−d)/2. The ratio t₁/[(h₁−d)/2] may be optimized depending on the specific application scenario and can be in the range of 1 to 5. In other words, according to the exemplary embodiment of FIG. 2, the decoupling structure 201 is formed by a tapered portion of the flange interface 202, wherein (but without the disclosure being limited thereto) the ratio between an axial extent of this tapered portion and a wall thickness of the tapered portion remaining toward the fluid channel can be in the range of 1 to 5. In this case, the fracture risk increases with the increasing value of this ratio t₁/[(h₁−d)/2], whereas the stiffness and thus the pressing-through of the parasitic deformations on the optical effective surface increases with the decreasing value of this ratio.

Further, as regards the reduction or minimization of deformations caused by unavoidable forces within the fluid channel arrangement on account of the fluid flowing therethrough, this reduction or minimization may also be implemented firstly by suitable reduction of the wall thickness (h₁−d)/2 and the decoupling structure introduced as a result. Secondly, the stiffness of the decoupling structure 201 for a given force generated in the fluid channel arrangement may be minimized by a suitable increase in the parameter t₁.

Within the scope of the above-described dimensioning of the flange connection according to the disclosure and of the flange interface for example, it is to be observed that the stiffness of the decoupling structure 201 cannot be reduced to an absolute minimum. Depending on the specific load spectrum (pressure load due to the fluid flowing in the fluid channel arrangement, external forces acting e.g. as a result of the fluid line system, etc.) and the fracture stress of the material used, the remaining wall thickness (h₁−d)/2 is still be large enough to ensure that resulting mechanical stresses will not lead to the mirror being damaged.

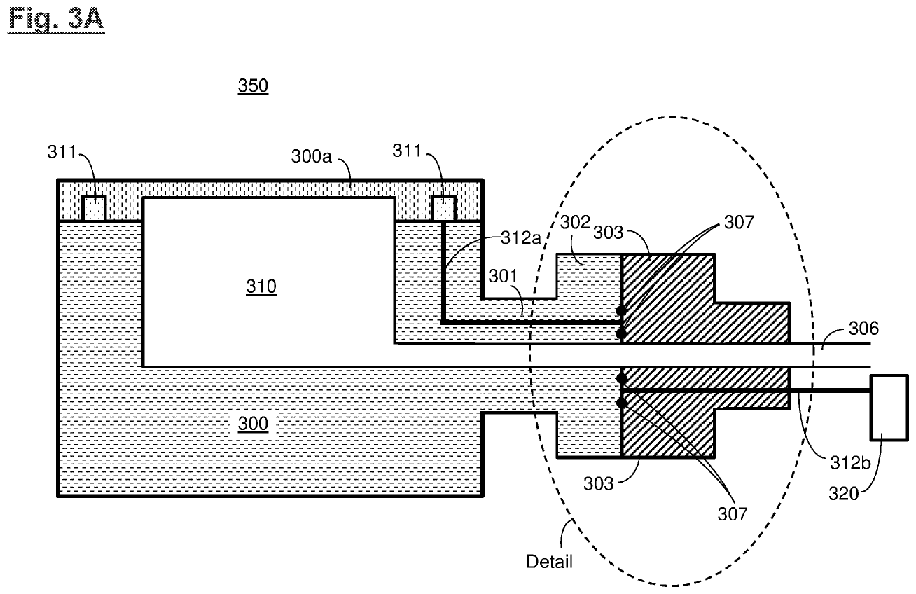

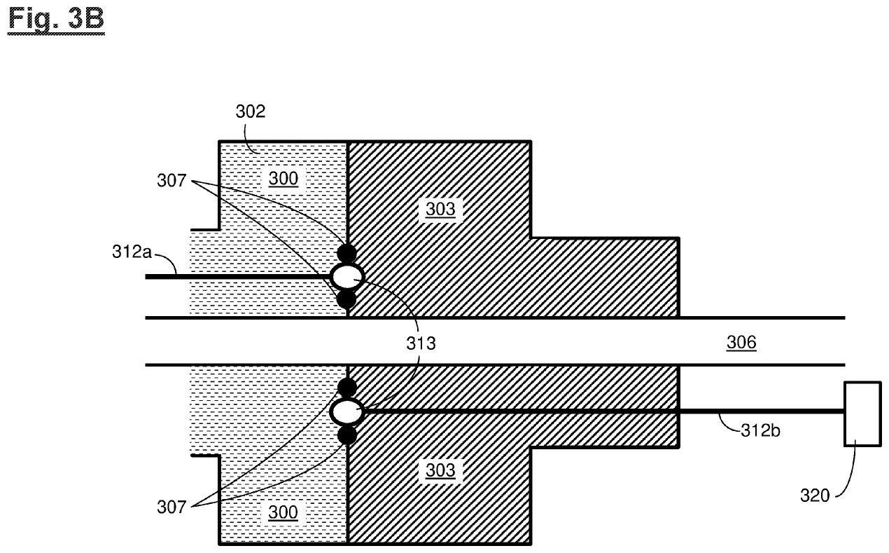

A further characteristic of the frictional flange connection according to the disclosure is the differential vacuum, which will still be described in detail with reference to FIGS. 3A-3B and is present in the entire assembly (including mirror main body, cover plate, flange and fluid line system) in embodiments of the disclosure. This differential vacuum is fed through the entire flange and passed at the interface between flange and mirror. This is realized by an intermediate space between the two O-rings of a seal 207 according to the double O-ring principle. The differential vacuum (=“support vacuum”) serves to monitor tightness in the assembly according to the disclosure or to monitor tightness of the mirror. Any leaks can be detected in real time as a result of permanently monitoring the differential vacuum. The associated system or machine can be shut down as soon as contamination of this differential vacuum is detected. This may take account of the fact that the mirror is operated in UHV surroundings (in the range from 10⁻¹⁰ mbar to 10⁻¹² mbar) when used as a synchrotron mirror and that the tightness standards are even higher than in comparison with EUV applications (10⁻⁹ mbar), for example.

FIGS. 3A-3B show schematic illustrations for explaining a possible embodiment of an assembly according to the disclosure. Components analogous or substantially functionally identical in comparison with FIG. 2 are denoted here by reference numerals increased by “100”.

According to FIGS. 3A-3B, “312a” and “312b” denote drilled holes which extend within the mirror main body 300 and the flange 303 and which each extend up to an intermediate space 313 located between the two O-rings of the seal 307 (and substantially surround the fluid channel 306 in a tubular manner). In this case, the drilled hole 312a provided in the mirror main body 300 extends to a groove 311 (formed purely by way of example with a rectangular cross section in the exemplary embodiment), which surrounds a fluid-receiving fluid volume 310.

Quantitatively, the vacuum pressure present in the outer surroundings of the mirror (referred to by “350” in FIG. 3A) may be in the range of (10⁻⁹-10⁻¹²) mbar, the vacuum pressure present in the fluid volume 310 may be in the range of (0.1-10) bar, and the vacuum pressure present within the bores 312a, 312b, the intermediate space 313 and the groove 311 (i.e. in the differential vacuum) may be in the range of (10⁻³-10⁻⁴) mbar.

The consequence of the above-described embodiment is that in the event of a leak, fluid escaping from the fluid channel 306 or the fluid volume 310 initially enters into the region of the differential vacuum provided according to the disclosure—i.e. into the groove 311 or the intermediate space 313 depending on the location of the leak-before reaching the (ultra-high) vacuum present in the outer environment of the mirror and may thus be detected via a monitoring device 320 connected to the drilled hole 312b. The monitoring device 320 may be embodied in any suitable manner and e.g. comprise a mass spectrometer, a gas detector or a moisture sensor. In the case of a corresponding detection of fluid entering one of the above-described regions of the differential vacuum, there can be a shutdown of the entire system or a fluid supply connected to the fluid channel 306, and so an undesired contamination of the (ultra-high) vacuum present in the outer surrounding region of the mirror is reliably avoided.

In embodiments, the assembly according to the disclosure may also comprise at least one further joining point in addition to the flange connection, wherein the monitoring device may then also serve to monitor a tightness of this/these further joining point(s) as regards escaping fluid.

Although reference has been made to a synchrotron mirror in the embodiments described above, the disclosure may furthermore also be realized in other optical systems, e.g. also in an illumination device or a projection lens of a microlithographic projection exposure system.

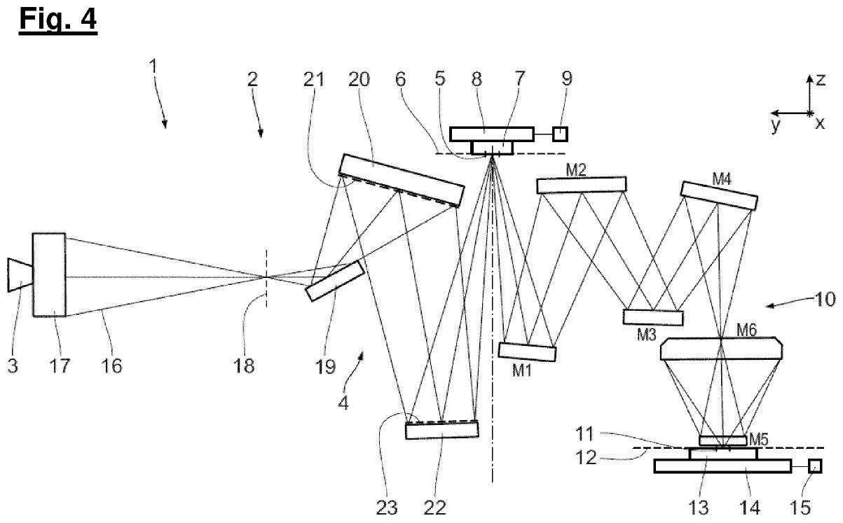

In this respect, FIG. 4 schematically shows in meridional section the possible structure of a microlithographic projection exposure apparatus designed for operation in the EUV. According to FIG. 4, the projection exposure apparatus 1 comprises an illumination device 2 and a projection lens 10. One embodiment of the illumination device 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination device. In this case, the illumination device does not comprise the light source 3. What is exposed here is a reticle 7 arranged in the object field 5. The reticle 7 is held by a reticle holder 8. The reticle holder 8 is displaceable by way of a reticle displacement drive 9, such as in a scanning direction. For explanatory purposes, a Cartesian xyz-coordinate system is depicted in FIG. 4. The x-direction runs perpendicularly to the plane of the drawing into the latter. The y-direction runs horizontally, and the z-direction runs vertically. The scanning direction runs in the y-direction in FIG. 4. The z-direction runs perpendicularly to the object plane 6.

The projection lens 10 serves for imaging the object field 5 into an image field 11 in an image plane 12. A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, such as in the y-direction. The displacement, firstly, of the reticle 7 by way of the reticle displacement drive 9 and, secondly, of the wafer 13 by way of the wafer displacement drive 15 may be implemented so as to be synchronized with one another.

The radiation source 3 is an EUV radiation source. The radiation source 3 emits EUV radiation, which is also referred to below as used radiation or illumination radiation. The used radiation can have a wavelength in the range of between 5 nm and 30 nm. The radiation source 3 can be for example a plasma source, a synchrotron-based radiation source or a free electron laser (FEL). The illumination radiation 16 emanating from the radiation source 3 is focused by a collector 17 and propagates through an intermediate focus in an intermediate focal plane 18 into the illumination optical unit 4. The illumination optical unit 4 comprises a deflection mirror 19 and, arranged downstream thereof in the beam path, a first facet mirror 20 (having schematically indicated facets 21) and a second facet mirror 22 (having schematically indicated facets 23).

The projection lens 10 comprises a plurality of mirrors Mi (i=1, 2, . . . ), which are consecutively numbered according to their arrangement in the beam path of the projection exposure apparatus 1. In the example illustrated in FIG. 4, the projection lens 10 comprises six mirrors M1 to M6. Alternatives with four, eight, ten, twelve or a different number of mirrors Mi are also possible. The penultimate mirror M5 and the last mirror M6 each have a through opening for the illumination radiation 16. The projection lens 10 is a doubly obscured optical unit. The projection lens 10 has an image-side numerical aperture that is greater than 0.5 and may also be greater than 0.6, and may be for example 0.7 or 0.75.

During operation of the microlithographic projection exposure apparatus 1, the electromagnetic radiation incident on the optical effective surface of the mirrors is partly absorbed and, as explained in the introduction, results in heating and an associated thermal expansion or deformation, which can in turn result in an impairment of the imaging properties of the optical system. The concept according to the disclosure can therefore also be applied to any desired mirror of the microlithographic projection exposure apparatus 1 from FIG. 4.

The disclosure may furthermore also be implemented in a projection exposure apparatus designed for operation in the DUV (i.e. at wavelengths less than 250 nm, such as less than 200 nm) or else in another optical system.

Although the disclosure has also been described by means of special embodiments, numerous variations and alternative embodiments, e.g. by combining and/or exchanging features of individual embodiments, can be discerned by a person skilled in the art. Accordingly, it is understood by those skilled in the art that such variations and alternative embodiments are also comprised by the present disclosure, and the scope of the disclosure is limited only in the sense of the appended claims and their equivalents.

What is claimed is:

1. An assembly, comprising:
a mirror comprising a mirror main body; and
a flange connection comprising:
a flange interface on the mirror main body;
a flange frictionally mounted on the flange interface; and
a seal between the flange and the flange interface to provide a differential vacuum,
wherein:
a fluid channel arrangement extends through the mirror main body;
the fluid channel arrangement comprises a fluid channel configured to have liquid flow therethrough; and
the fluid channel arrangement is couplable to a fluid line system via the flange connection.

2. The assembly of claim 1, wherein the seal comprises a double O-ring.

3. The assembly of claim 1, further comprising a monitor configured to monitor fluid escaping between the flange and the flange interface.

4. The assembly of claim 1, wherein the flange interface comprises a decoupling structure configured to reduce a transmission of force from the flange to the mirror main body.

5. The assembly of claim 4, wherein the decoupling structure comprises a tapered portion of the flange interface.

6. The assembly of claim 5, wherein the fluid channel extends in an axial direction in the tapered portion, and a ratio between an axial extent of the tapered portion and a wall thickness of the tapered portion toward the fluid channel is from one to five.

7. The assembly of claim 1, wherein a screw connection mounts the flange to the flange interface.

8. The assembly of claim 7, wherein:
the screw connection extends along a portion of the flange interface; and
for the portion of the flange interface, a ratio of its extent in a direction perpendicular to the screw direction to the extent in the screw direction is from two to 10.

9. The assembly of claim 1, wherein the mirror comprises:
a cover plate bonded to the mirror main body; and
a reflection layer system supported by the cover plate.

10. The assembly of claim 9, wherein the cover plate is monolithically direct bonded or monolithically fusion bonded to the mirror main body.

11. The assembly of claim 1, wherein the mirror main body comprises a silicon-containing material.

12. The assembly of claim 1, wherein the mirror is configured to reflect radiation at a wavelength of less than 30 nm.

13. The assembly of claim 1, wherein the mirror is configured to reflect radiation at wavelength of less than 0.1 nm.

14. An optical system, comprising:
an assembly according to claim 1.

15. The assembly of claim 14, wherein the optical system comprises a beam guiding unit of a synchrotron or a free-electron laser.

16. The optical system of claim 14, wherein the optical system is a synchrotron.

17. The optical system of claim 14, wherein the optical system is a projection lens of a microlithographic projection exposure apparatus, or the optical system is an illumination device of a microlithographic projection exposure apparatus.

18. An assembly, comprising:
a mirror comprising a mirror main body;
a flange connection, comprising:
a flange interface on the mirror main body; and
a flange frictionally mounted on this flange interface; and
a monitor configured to monitor fluid escaping between the flange and the flange interface,
wherein:
a fluid channel arrangement extends through the mirror main body;
the fluid channel arrangement comprises a fluid channel configured to have liquid flow therethrough; and
the fluid channel arrangement is couplable to a fluid line system via the flange connection.

19. The assembly of claim 18, wherein the monitor is configured to monitor fluid escape without influencing an external vacuum environment of the mirror.

20. The assembly of claim 18, wherein the monitor is configured to detect fluid entering a region between the flange and the flange interface.

21. The assembly of claim 18, wherein the monitor comprise at least one member selected from the group consisting of a mass spectrometer, a gas detector and a moisture sensor.

22. The assembly of claim 18, wherein the assembly comprises a joining point in addition to the flange connection, and the monitor is configured to monitor fluid escaping at the joining point.

23. An optical system, comprising:
an assembly according to claim 22.
